(19) United States
(12) Patent Application Publication
(10) Pub. No.: US 2008/0191288 A1
(43) Pub. Date: Aug. 14, 2008

(54) SEMICONDUCTOR DEVICE AND METHOD OF MANUFACTURING THE SAME

(75) Inventors: Yong-Hyun KWON, Gyeonggi-do (KR); Jae-Seung HWANG, Gyeonggi-do (KR); Jun SEO, Gyeonggi-do (KR); Sung-Il CHO, Seoul (KR); Sang-Joon PARK, Seoul (KR); Eun-Young KANG, Seoul (KR); Hyun-Chul KIM, Seoul (KR); Jung-Hoon CHAE, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/030,118

(22) Filed: Feb. 12, 2008

(30) Foreign Application Priority Data
Feb. 12, 2007 (KR) 2007-0014469

(51) Int. Cl. H01L 21/336

(52) U.S. Cl. 257/383; 257/E21.432

(57) ABSTRACT

In a semiconductor device including a transistor having an embedded gate, and methods of manufacturing the same, a substrate is divided into first and second regions. A gate trench is formed in the first region, a first gate structure partially fills the gate trench and a passivation layer pattern is provided inside the gate trench and positioned on the first gate structure. A first source/drain is provided adjacent to sidewalls of the first gate structure. A second gate structure is provided in the second region and has a silicon oxide layer, a conductive layer pattern and a metal silicide layer pattern stacked on the conductive layer pattern. A second source/drain is provided adjacent to sidewalls of the second gate structure. Defects due to formation of reactants may be reduced in a formation process of the above-described semiconductor device, improving reliability and operating characteristics.

### CROSS-REFERENCE TO RELATED APPLICATIONS

This application claims the benefit of foreign priority under 35 U.S.C. § 119 to Korean Patent Application No. 2007-14469, filed on Feb. 12, 2007, the disclosure of which is incorporated herein by reference in its entirety.

### BACKGROUND

1. Field of Invention

Example embodiments of the present invention relate to a semiconductor device and a method of manufacturing the same. More particularly, example embodiments of the present invention relate to a semiconductor device including a transistor that has an embedded gate in a region of a portion of a substrate and a method of manufacturing the same.

2. Description of the Related Art

Semiconductor devices are currently being improved to be capable of operating at high speeds at low voltages. Further, manufacturing processes of semiconductor devices are being improved to enhance degrees of integration. In a metal-oxide semiconductor field-effect transistor (MOSFET) used as a semiconductor device, a channel length of the MOSFET may be reduced for high speed operation. However, in a general planar-type MOSFET, as the channel length becomes shorter, the influence of an electric field due to a drain voltage may become greater. Further, a short channel effect may be generated as the channel drivability of a gate electrode is degraded. Moreover, carrier mobility and current drivability may be reduced due to increases in channel density. Also, a junction leakage current may be increased due to decreases in source/drain junction depth.

To form a field-effect transistor (FET) having high performance and a narrower upper surface, a method of increasing a channel length by etching a channel region of a lower portion of a gate is known. For example, Korean Patent No. 10-0344733 is understood to disclose a method of forming a transistor that includes forming a trench at a surface portion of a substrate, forming a gate electrode in the trench, and forming source/drain regions around an upper portion of the trench.

Further, a material used as a gate electrode of the FET may be a metal or a metal nitride instead of polysilicon. The reason is that, when a gate electrode is formed using only polysilicon, it is difficult to reduce the line width of the gate electrode below the limits of a photolithographic process. Moreover, in the case of polysilicon material, doping of impurities is required, and in a case where stress is applied to a layer, changes in the mobility of electrons and holes may occur and change characteristics of each device. Further, since the resistance of polysilicon is high, the operating speed becomes slower.

For example, a method of forming a gate electrode having a structure in which polysilicon and a metal are stacked in order to form a gate having low resistance is understood to be disclosed in U.S. Pat. No. 6,236,094. Further, a method of forming a gate oxide layer and a metal gate after a trench is formed in a gate formation portion is understood to be disclosed in U.S. Pat. No. 6,033,963.

However, in a case where an embedded gate including a metal material is formed inside a trench as mentioned above, unexpected defects may frequently occur after the trench is formed in the gate formation portion.

More particularly, a planar-type transistor or a transistor having the embedded gate may be formed on each of the regions of the substrate. Thus, a process for forming the transistor having the embedded gate, and a process for forming the planar-type transistor may be individually performed. However, when the process for forming the planar-type transistor is performed the embedded gate formation portion may be oxidized or changed. Further, a gate oxide layer included in the embedded gate may be attacked.

As mentioned above, reactants formed by oxidization or changes in an embedded gate formation portion may not be etched easily by a conventional etching process. Thus, defects where the embedded gate is not formed normally or is shorted with other conductive patterns adjacent to the embedded gate may occur. Moreover, the reliability of a semiconductor device may be reduced due to the reactants.

### SUMMARY

Example embodiments of the present invention provide a semiconductor device of high reliability and performance including an embedded transistor and a planar transistor.

Example embodiments of the present invention provide a method of manufacturing the above-mentioned semiconductor device.

One example embodiment described herein can be generally characterized as a semiconductor device that includes a substrate having a first region and a second region, wherein a gate trench is formed in the first region; a first gate structure partially filling the gate trench; a passivation layer pattern provided in the gate trench and on the first gate structure; first source/drain regions adjacent to sidewalls of the first gate structure; a second gate structure provided on a surface of the substrate in the second region of the substrate, the second gate structure having a gate dielectric layer, a conductive layer pattern and a metal silicide layer pattern stacked on the conductive layer pattern; and second source/drain regions adjacent to sidewalls of the second gate structure.

### BRIEF DESCRIPTION OF THE DRAWINGS

The above and other features and advantages of the embodiments described herein will become readily apparent by reference to the following detailed description when considered in conjunction with the accompanying drawings wherein:

FIG. 1 is a cross-sectional view illustrating an exemplary semiconductor device in accordance with Example Embodiment 1;

FIGS. 2 to 9 are cross-sectional views illustrating an exemplary method of manufacturing the semiconductor device in FIG. 1;

FIG. 10 is a cross-sectional view illustrating an exemplary dynamic random access memory (DRAM) device in accordance with Example Embodiment 2; and

FIGS. 11 to 21 are cross-sectional views illustrating an exemplary method of manufacturing the DRAM device in FIG. 10.

### DETAILED DESCRIPTION

Example embodiments of the present invention are described more fully hereinafter with reference to the accompanying drawings. These embodiments may, however, be realized in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-sectional illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### Example Embodiment 1

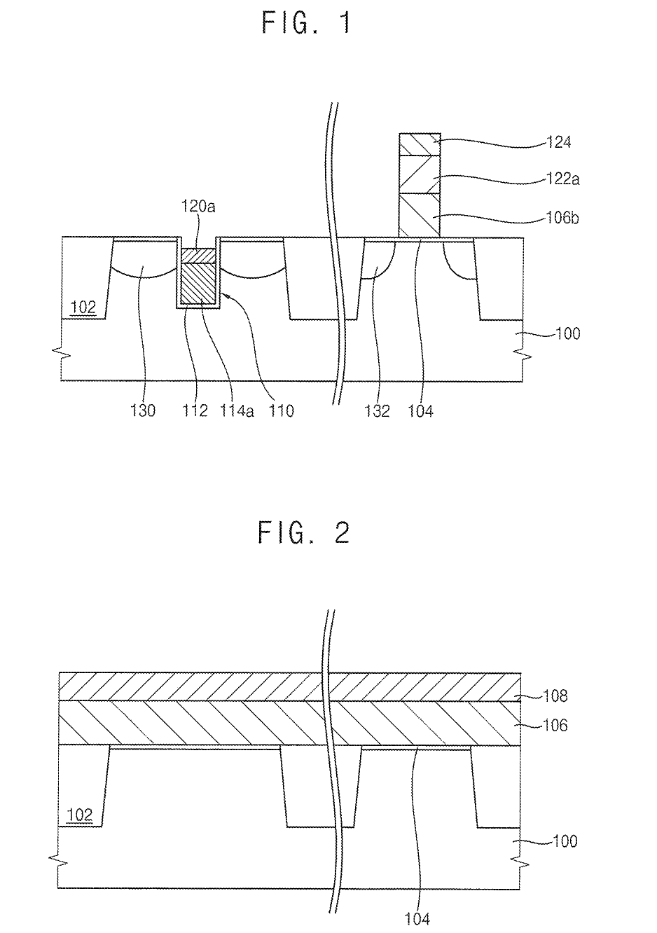

FIG. 1 is a cross-sectional view illustrating an exemplary semiconductor device in accordance with Example Embodiment 1.

Referring to FIG. 1, a substrate 100 divided into a first region (e.g. the left-illustrated region) and a second region (e.g., the right-illustrated region) is provided. The first region of the substrate 100 corresponds to a cell region and the second region corresponds to a peripheral circuit region.

Further, a trench may be formed at a surface portion of the substrate 100. An isolation layer 102 may fill the trench. The substrate 100 is divided into an active region and an isolation region by the isolation layer 102.

A gate trench 110 is formed at a portion of the first region of the substrate 100 where a gate is to be formed. Though not shown, when the gate formed in the first region is used for a word line, the gate trench 110 has a linear shape. That is, the gate trench 110 has a shape in which both an active region for a gate of a transistor and the isolation region adjacent to the active region are etched.

A first gate structure partially filling up the gate trench 110 is provided. The first gate structure includes a first gate oxide layer 112 and a first gate electrode 114a.

In this example embodiment, the first gate oxide layer 112 includes a material such as silicon oxide provided on a side face and a bottom face of the gate trench 110. Further, the first gate pattern 114a may include a material such as a metal partially filling the gate trench 110.

That is, an upper surface of the first gate electrode pattern 114a is lower than that of the substrate 100. The metal of the first gate electrode pattern 114a may include, for example, titanium nitride.

A passivation layer pattern 120a for protecting the first gate electrode pattern 114a is provided on the first gate electrode pattern 114a. An upper surface of the passivation layer pattern 120a is located inside the gate trench 110. The passivation layer pattern 120a may include a material such as silicon nitride, silicon oxynitride, polysilicon, or the like or a combination thereof.

First source/drain regions 130 are provided under surfaces of the substrate 100 and adjacent to sidewalls of the first gate structure.

A second gate structure is provided on a surface of the second region of the substrate 100. The second gate structure includes a stacked structure of a first silicon oxide layer 104, a conductive layer pattern 106b, a metal silicide layer pattern 122a and a second hard mask pattern 124. In this example embodiment, the second gate structure may include a gate oxide layer (e.g., including a material such as silicon oxide) and a gate electrode (e.g., including a stacked structure of a polysilicon layer, a tungsten silicide pattern and a silicon nitride layer). As shown in FIG. 1, because a gate trench is not formed in the second region of the substrate 100, a transistor is formed on a flat surface of the substrate. Further, the material of the gate electrode in the transistor formed in the second region may be different from that of the gate electrode in the transistor formed in the first region.

Second source/drain regions 132 are provided under surfaces of the substrate 100 and adjacent to sidewalls of the second gate structure.

Since the passivation layer pattern is provided on the first gate structure of the semiconductor device, oxidation or changes in characteristics of the first gate structure may be reduced. Therefore, the semiconductor device may have higher reliability and performance.

FIGS. 2 to 9 are cross-sectional views illustrating an exemplary method of manufacturing the semiconductor device in FIG. 1.

Referring to FIG. 2, a substrate 100 divided into first and second regions is provided. The first region of the substrate 100 corresponds to a cell region and the second region corresponds to a peripheral circuit region.

An isolation layer 102 is formed by performing a shallow trench isolation (STI) process on the substrate 100. The substrate 100 is divided into an active region and a device isolation region by the isolation layer 102.

The substrate 100 is thermally oxidized to form a first silicon oxide layer 104. The first silicon oxide layer 104 is used as a second gate oxide layer of a planar transistor in the second region. A first conductive layer 106 is formed on the first silicon oxide layer 104. The first conductive layer 106 is used as a portion of a gate electrode of a planar transistor in the second region. In this example embodiment, a polysilicon layer is formed as the first conductive layer 106.

A hard mask layer 108 is formed on the first conductive layer 106. The hard mask layer 108 may include silicon nitride.

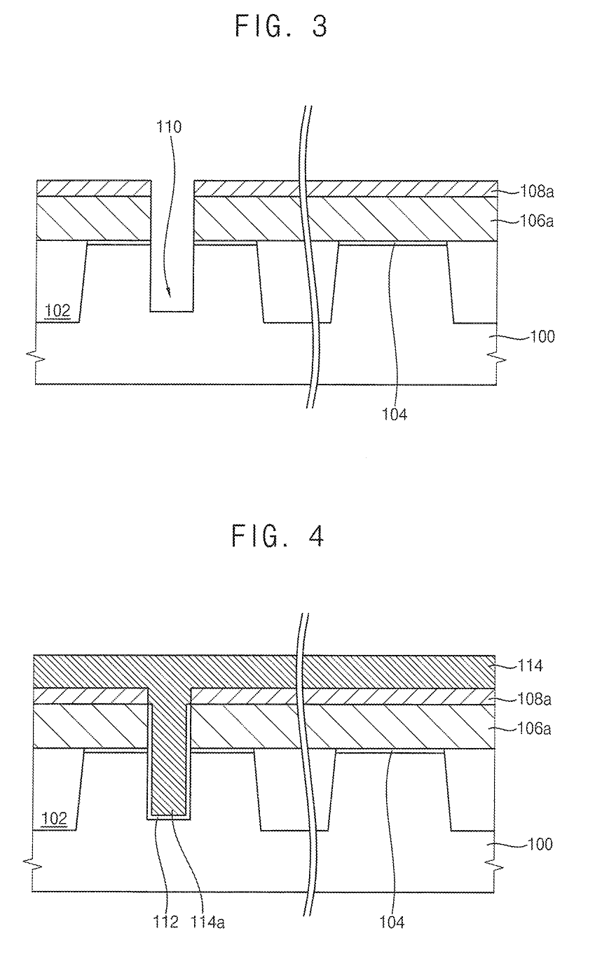

Referring to FIG. 3, a first hard mask pattern 108a selectively exposing a portion of the first region where a gate is to be formed is formed by patterning the hard mask layer 108. In one embodiment, the first hard mask pattern 108a may be characterized as covering the entire surface of the second region of the substrate and only the portion of the first region where the gate is to be formed is exposed.

Then, using the first hard mask pattern 108a as an etching mask, the first conductive layer 106, the first silicon oxide layer 104 and the exposed substrate 100 are etched in order to form a first conductive layer pattern 106a and a gate trench 110.

Though not shown in the figures, when a gate electrode of a transistor formed in the first region is used as a word line, the gate trench 110 has a linear shape. Therefore, the gate trench 110 may be formed in the isolation region next to the active region, as well as the active region.

Referring to FIG. 4, a second silicon oxide layer is formed by performing a thermal oxidation process so that surfaces of the substrate 100 exposed to sidewalls of the gate trench 110 are oxidized. The second silicon oxide layer is provided as a first gate oxide layer 112 of an embedded transistor formed in the first region.

Thereafter, the second conductive layer 114 is formed by depositing metal materials to completely fill the gate trench 110 and gaps of the first conductive layer pattern 106a and the first silicon oxide layer 104. Here, the second conductive layer 114 is formed on the first conductive layer pattern 106a in the second region.

In one embodiment, the second conductive layer 114 is formed using metal material having superior step coverage so that the gaps of the first conductive layer pattern 106a, the first silicon oxide layer 104 and the inside of the gate trench 110 may be filled without voids. In this example embodiment, the second conductive layer 114 is formed by depositing a material such as titanium nitride.

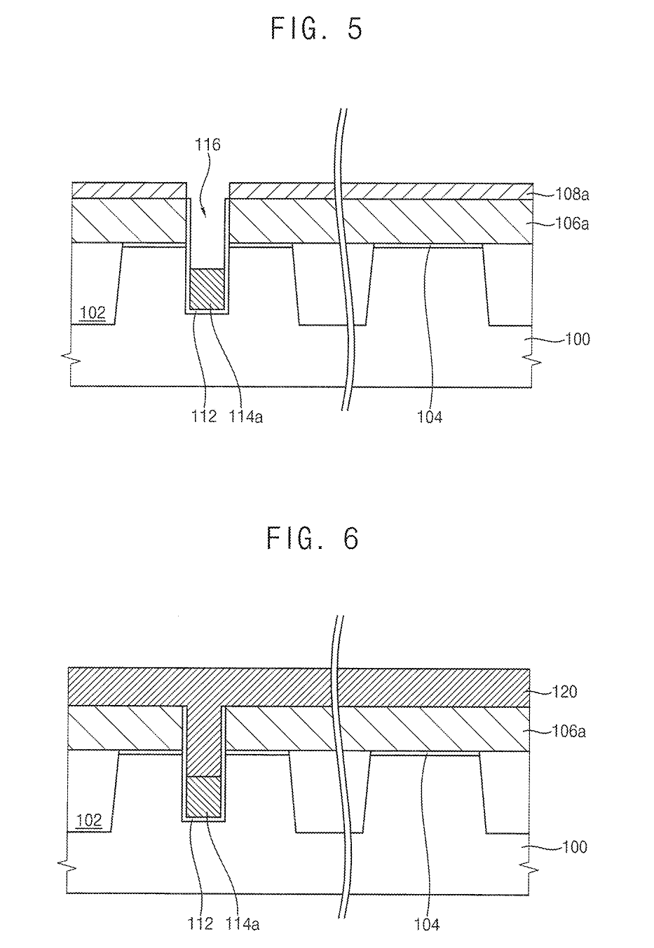

Referring to FIG. 5, a first gate electrode pattern 114a partially filling the gate trench 111 is formed by etching-back the second conductive layer 114 by a dry etching process.

Here, the second conductive layer 114 is dry-etched so that an upper surface of the first gate electrode pattern 114a is lower than that of the substrate 100. When the upper surface of the first gate electrode pattern 114a is lower than that of the substrate 100 by a thickness of less than or equal to about 200 Å, the passivation layer pattern may be formed too thin in a following process. Also, when the upper surface of the first gate electrode pattern 114a is lower than that of the substrate 100 by a thickness of greater than or equal to about 1,000 Å, the first gate electrode pattern 114a may be formed too thin due to an increase of etching amount of the second conductive layer 114. Therefore, in one embodiment, the upper surface of the first gate electrode pattern 114a may be lower than that of the substrate 100 by a thickness of between about 200 Å and about 1,000 Å.

When the second conductive layer is formed of titanium nitride, the etching process may be performed by supplying a direct current (DC) voltage under about 500 V, and supplying etching gas under a pressure of about 1 to about 50 mTorr. The etching gas may include Cl₂, HBr, NF₃, CF₃, CHF₃. These may be used alone or in a mixture thereof. Further, inert gases such as N₂ and Ar may be introduced with the etching gas.

As mentioned above, a first opening 116 is formed between the first silicon oxide layer 104, the first conductive layer pattern 106a and the first hard mask pattern 108a by dry-etching the second conductive layer 114.

Further, the second conductive layer 114 in the second region may be completely removed by the dry etching process. Therefore, the first hard mask pattern 10a in the second region may be exposed.

Referring to FIG. 6, the first hard mask pattern 108a formed in the first and second region is removed. The removal of the first hard mask pattern 108a may be performed by an etching process or an etch-back process.

In this example embodiment, when the first hard mask pattern 108a includes a material such as silicon nitride, the first hard mask pattern 108a may be removed using phosphoric acid. Alternatively, the first hard mask pattern 108a may be removed by a dry etching process. The etching gas may include CH₂F₂, CHF₃, CH₃F, CH₄, CF₄, etc. These may be used alone or in a mixture thereof. The etching gas may be used with argon, oxygen or nitrogen.

The first hard mask pattern 108a is removed to form a second opening, which has a lower depth than that of the first opening 116, between the first silicon oxide layer 104 and the first conductive layer pattern 106a.

A passivation layer 120 is formed to completely fill the second opening. The passivation layer 120 may function to protect the first gate electrode pattern 114a thereunder in a following process for forming a metal silicide layer. The passivation layer 120 may include a material such as silicon nitride, silicon oxynitride, polysilicon, or the like or a combination thereof. In this example embodiment, the passivation layer is exemplarily formed from silicon nitride.

Before forming the passivation layer 120, a process for forming a silicon oxide layer (not shown) may be additionally performed. The silicon oxide layer may be formed to cure damages to the active region during an anisotropic etching process for the second conductive layer and a removing process for the first hard mask pattern 108a.

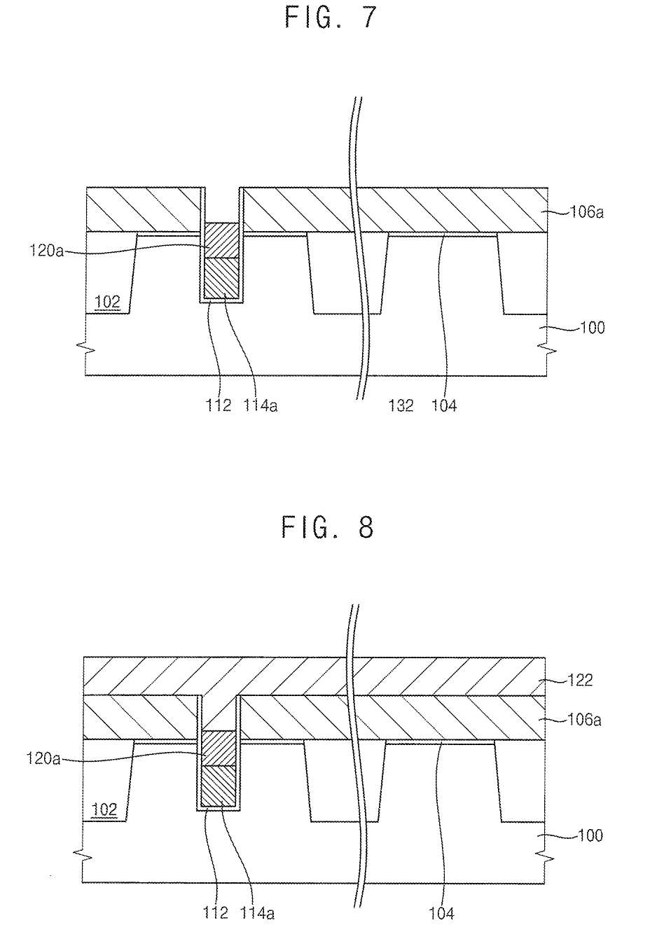

Referring to FIG. 7, a passivation layer pattern 120a having an upper surface lower that that of the first conductive layer pattern 106a is formed in the second opening by etching-back the passivation layer 120 by a dry etching process.

Here, the passivation layer 120 formed in the second region may be completely removed. Therefore, the first conductive layer pattern 106a in the second region may be exposed.

Referring to FIG. 8, a tungsten silicide layer 122 is formed on the first conductive layer pattern 106a and the passivation layer pattern 120a. The tungsten silicide layer 122 is formed by a chemical vapor deposition (CVD) process using a tungsten source gas and a silicon source gas.

Here, the tungsten silicide layer 122 is formed on the first conductive layer pattern 106a and passivation layer pattern 120a of the first region. Therefore, the upper surface of the first gate electrode pattern 114a may not directly contact the tungsten silicide layer 122.

Conventionally, since the tungsten silicide layer is formed to directly contact the upper surface of the first gate electrode pattern, the surface of the first gate electrode pattern is abnormally oxidized and byproducts are frequently formed. However, according to the above-mentioned method, since the tungsten silicide layer 122 is not formed on the upper surface of first gate electrode pattern 114a, the abnormal oxidation of surface of the first gate electrode pattern 114a may be prevented. Therefore, short defects due to the byproducts formed by the abnormal oxidation may be prevented.

Further, the tungsten silicide layer 122 may be formed on the first conductive layer pattern 106a in the second region. The tungsten silicide layer 122 may be used as a portion of a gate electrode of a planar transistor formed in the second region.

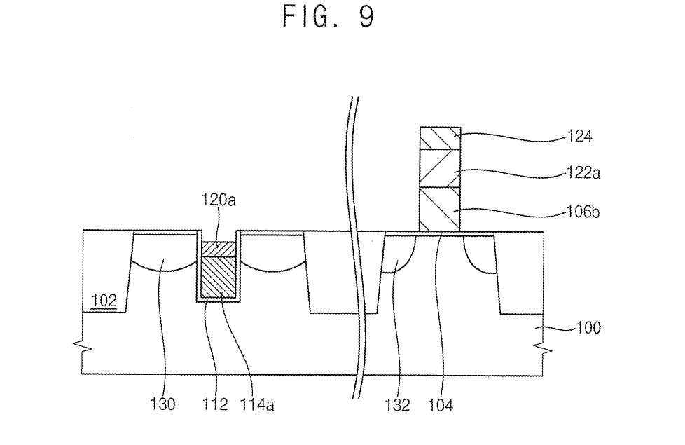

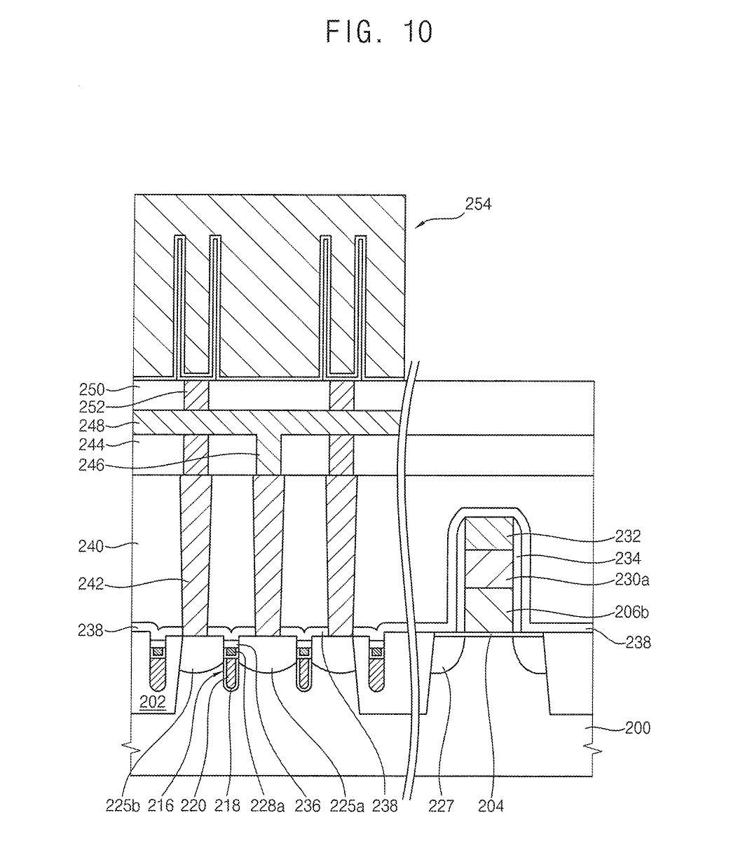

Referring to FIG. 9, a second hard mask pattern 124 is formed on the tungsten silicide layer 122. The second hard mask pattern 124 is used as a mask for patterning the gate electrode of a planar transistor in the second region.

Further, in a following etching process, the tungsten silicide layer formed in the first region may be completely removed. Therefore, the second hard mask pattern 124 may have a shape configured to expose the entire first region.

Then, the tungsten silicide layer 122 and first conductive layer pattern are etched using the second hard mask pattern 124 as an etching mask.

By performing the above-mentioned process, the tungsten silicide layer 122 and the first conductive layer pattern 106a of the first region may be completely removed so that a first gate structure of an embedded transistor is formed. The first gate structure is in the gate trench and includes the first gate electrode pattern 114a and the passivation layer pattern 120a stacked on the first gate electrode pattern 114a.

Due to the slight etching of the passivation layer pattern 120a in the above-mentioned etching process, as shown in FIG. 9, the height of the passivation layer pattern 120a may be lower than that of the passivation layer pattern 120a before performing the etching process.

Further, a second gate structure of a planar transistor may be formed in the second region. The second gate structure is arranged on a planar upper surface of the substrate and includes a stacked structure of a silicon oxide layer 104, a conductive layer pattern 106b, a tungsten silicide pattern 122a and the second hard mask pattern 124.

Thereafter, impurities for forming source/drain region are implanted into the substrate 100. By performing the above-mentioned process, first source/drain regions 130 may be formed under a surface of the substrate adjacent to sidewalls of the first gate structure and second source/drain 132 regions may be formed under a surface of the substrate adjacent to sidewalls of the second gate structure.

### Example Embodiment 2

FIG. 10 is a cross-sectional view illustrating an exemplary dynamic random access memory (DRAM) device in accordance with Example Embodiment 2.

Referring to FIG. 10, a substrate 200 divided into a first region (e.g., the left-illustrated region) and second region (e.g., the right-illustrated region) is prepared. The first region of the substrate 200 corresponds to a cell region and the second region corresponds to a peripheral circuit region.

Further, an isolation trench may be formed at a surface portion of the substrate 200. An isolation layer 202 may fill the isolation trench. The substrate 200 is divided into an active region and a device isolation region by the isolation layer 202. The active region of the substrate has an isolated (e.g., island) shape.

A gate trench 216 to be formed as a word line is formed on the first region of the substrate. The gate trench 216 has a linear shape elongated along a first direction from etching of the isolation region next to an active region for a gate as well as the active region for the gate.

In this example embodiment, two unit cells are formed in one isolated active region. Thus, two gate trenches 216 are formed side-by-side in the isolated active region.

A first gate structure is provided in the gate trench 216. The first gate structure includes a first gate oxide layer 218 and a first gate electrode 220.

In this example embodiment, the first gate oxide layer 218 includes a material such as silicon oxide provided on a side face and a bottom face of the gate trench 216. Further, the first gate electrode 220 may include a material such as a metal partially filling the gate trench 216. That is, an upper surface of the first gate electrode 220 is lower than that of the substrate 200. The metal of first gate electrode 220 may include, for example, titanium nitride.

Since the active region has an isolated shape, a distance between the first gate structures may be relatively reduced when the line width of the first gate structure is increased. However, the resistance of a contact pad 242 connecting to source/drain regions may be increased when the distance between the first gate structures is reduced. Therefore, the line width of the first gate structure can be narrower than the distance between the first gate structures.

A passivation layer pattern 228a is provided on the first gate electrode 220 to protect the first gate electrode 220. An upper surface of the passivation layer pattern 228a is located inside the gate trench 216. The passivation layer pattern 228a may include a material such as silicon nitride, polysilicon or the like or a combination thereof. Further, an upper passivation layer pattern 236 may be provided on the passivation layer pattern 228a.

In this example embodiment, the passivation layer pattern 228a may include polysilicon and the upper passivation layer pattern 236 may include silicon nitride. An upper surface of the upper passivation layer pattern 236 is lower than that of the substrate 200.

First source/drain regions 225a and 225b are provided under surfaces of the substrate 200 and adjacent to sidewalls of the first gate structure.

A second gate structure is provided on a surface of the second region of the substrate 200. The second gate structure may include a stacked structure including a first silicon oxide layer 204, a conductive layer pattern 206b, a metal silicide layer pattern 230a and a second hard mask pattern 232. In this example embodiment, the second gate structure may include a gate oxide layer (e.g., including a material such as silicon oxide) and a gate electrode (e.g., including a stacked structure of a polysilicon pattern, a tungsten silicide pattern and a silicon nitride layer pattern).

Spacers 234 are provided on sidewalls of the second gate structure. The spacers 234 may include substantially the same material as that of the upper passivation layer pattern 236.

Second source/drain regions 227 are provided under surfaces of the substrate 200 and adjacent to sidewalls of the second gate structure.

An etch-stop layer 238 is provided on the first region and second region of the substrate 200 whereon the first and second gate structures are formed. The etch-stop layer 238 may include a material such as silicon nitride.

A first insulating interlayer 240 is provided on the etch-stop layer 238. The first insulating interlayer 240 may include a material such as silicon oxide. In this example embodiment, the insulating interlayer may, for example, include a high-density plasma (HDP) oxide layer, a tetraethyl orthosilicate (TEOS) layer, an undoped silicate glass (USG) layer, or the like or a combination thereof.

Contact holes exposing surfaces of the substrate 200 next to sidewalls of the first gate structure are formed to penetrate the first insulating interlayer 240 and the etch-stop layer 238. A contact pad 242 electrically connected to the source/drain regions 225a and 225b is provided inside the contact holes.

A second insulating interlayer 244 is provided on the contact pad 242 and the first insulating interlayer 240. A bit line contact 246 penetrates the second insulating interlayer 244 and is electrically connected to a portion of the contact pad 242. A bit line 248 is provided on the second insulating interlayer 244 and is electrically connected to the bit line contact 246.

A third insulating interlayer 250 completely covering the bit line 248 is provided on the second insulating interlayer 244.

A storage node contact 252 penetrates the third and second insulating interlayers 250 and 244 and is electrically connected to the remaining contact pad 242.

A cylindrical capacitor 254 connected to the storage node contact 252 is provided on the third insulating interlayer 250.

In a DRAM device according to this example of embodiment, a contact area of a contact pad connecting to source/drain regions may be increased. Further, due to the passivation layer pattern, shorts occurring between the contact pad and the first gate structure may be reduced even if a misalignment occurs when the contact pad is formed.

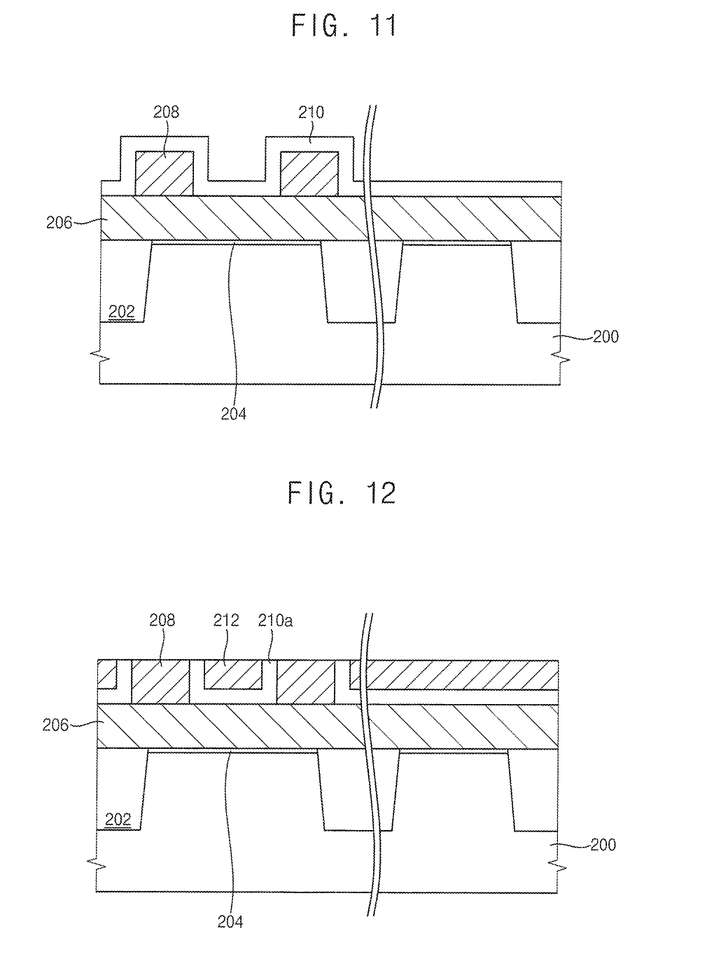

FIGS. 11 to 21 are cross-sectional views illustrating an exemplary method of manufacturing the DRAM device in FIG. 10.

Referring to FIG. 11, a substrate 200 divided into a first region and a second region is prepared. The first region of the substrate 200 corresponds to a cell region, the second region corresponds to a peripheral circuit region.

A pad oxide layer (not shown) is formed on the substrate 200. Then, a first hard mask pattern (not shown) used as an etching mask when forming an isolation trench, is formed. The device isolation trench (not shown) is formed by sequentially etching the pad oxide layer and substrate corresponding to an isolation region using the first hard mask pattern as an etching mask.

A trench inner wall oxide layer (not shown) is formed by thermally oxidizing exposed silicon of sidewalls and the bottom of the isolation trench. Also, a nitride layer liner (not shown) is formed on the trench inner wall oxide layer and surface of the first hard mask pattern. Then, a silicon oxide layer (not shown) is formed to fill the isolation trench and to cover the first hard mask pattern. Examples of the silicon oxide layer may, for example, include an HDP oxide layer, a TEOS layer, a USG layer, or the like or a combination thereof.

An isolation layer 202 filling the isolation trench is formed by performing a chemical mechanical polishing (CMP) process on the silicon oxide layer to expose the first hard mask pattern. The substrate 200 is divided into an isolation region and an active region by forming the isolation layer 202. Then, the first hard mask pattern is removed.

Then, the first silicon oxide layer 204 is formed by thermally oxidizing surface of the substrate 200 wherein the active region and the device isolation region are divided. The first silicon oxide layer 204 is used as a second gate oxide layer of a planar transistor in the second region. A first polysilicon layer 206 is formed on the first silicon oxide layer 204. The first polysilicon layer 206 is used as a portion of a gate electrode of the planar transistor in the second region.

A first silicon nitride layer (not shown) is formed on the first polysilicon layer 206. A photoresist pattern (not shown) is formed on the first silicon nitride layer. A first dummy pattern 208 is formed on the first region by etching the first silicon nitride layer using the photoresist pattern as an etching mask. The first dummy pattern 208 formed on the first region has a linear shape elongated along a first direction.

The photoresist pattern is not formed on the second region. Therefore, by performing the etching process, the first silicon nitride layer formed on the second region may be completely removed.

Thereafter, a second silicon oxide layer 210 is formed along the first dummy pattern 208 and a surface of the exposed substrate 200. As will be described in greater detail below, a gate trench is subsequently formed under a surface of the substrate in contact with the second silicon oxide layer 210 formed on sidewalls of the first dummy pattern 208. Therefore, an inner width of the gate trench may be adjusted by adjusting a deposition width of the second silicon oxide layer 210.

Referring to FIG. 12, a second silicon nitride layer (not shown) is formed to fill spaces between the second silicon oxide layers 210.

Then, the second silicon nitride layer and the second silicon oxide layer 210 are polished to expose upper surfaces of the first dummy patterns 208. By performing the polishing process, the second silicon nitride layers are separated to form a second dummy pattern 212. Further, a second silicon oxide layer pattern 210a may be formed to surround a side face and a bottom face of the second dummy pattern 212.

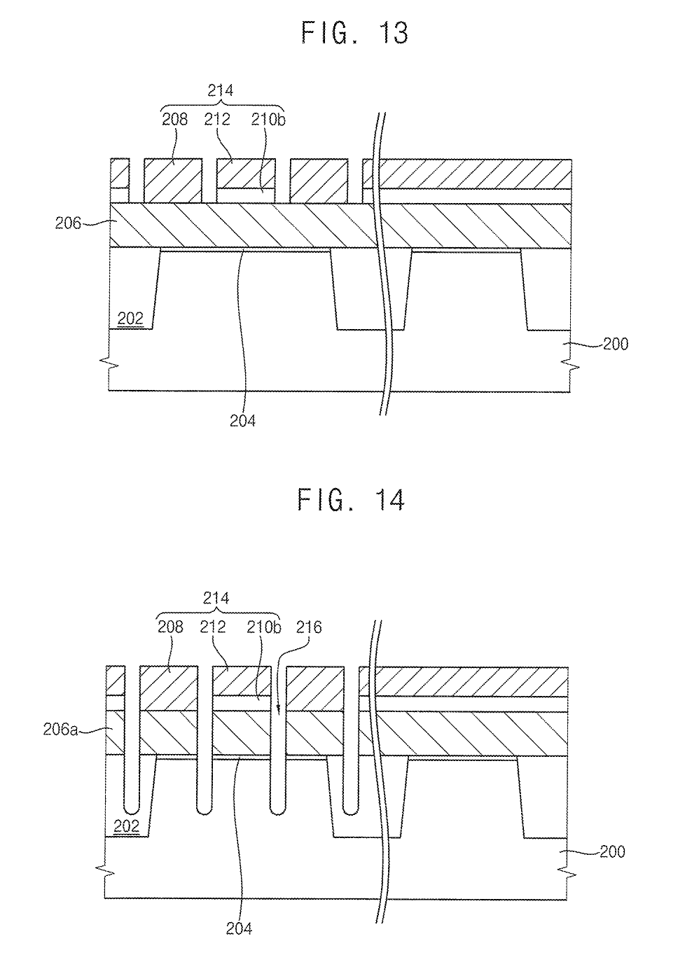

Referring to FIG. 13, second hard mask patterns 214 are formed to form a gate trench by removing a portion of the second silicon oxide layer pattern 210a formed between the first and second dummy patterns 208 and 212.

That is, at least one of the second hard mask patterns 214 formed in the first region is the first dummy pattern 208 and includes silicon nitride, and at least another one of the second hard mask patterns 214 is a stacked structure including a silicon oxide layer pattern 210b and the second dummy pattern 212.

As shown in the figures, a width of an exposed portion when the second hard mask pattern 214 is narrower than that of an exposed portion when a mask pattern is formed by patterning through a conventional photolithographic process. Therefore, a trench having a very narrow inner width may be formed as exemplarily described with respect to FIG. 14.

Further, the second hard mask pattern 214 may have a shape configured to completely cover the second region.

Referring to FIG. 14, a gate trench 216 is formed by etching the exposed substrate 200 and the isolation layer 202 using the second hard mask pattern 214 as an etching mask. Because a width of the substrate 200 exposed by the second hard mask pattern 214 is narrow, an inner width of the gate trench 216 is very narrow.

In a case where an inner width of the gate trench 216 is reduced, a width of the active region of the substrate 200 next to sidewalls of the gate trenches 216 may be relatively increased. Therefore, a contact area of a contact plug formed on the active region next to sidewalls of the gate trenches 216 in a subsequent process may be increased, and contact resistance may be reduced as a result.

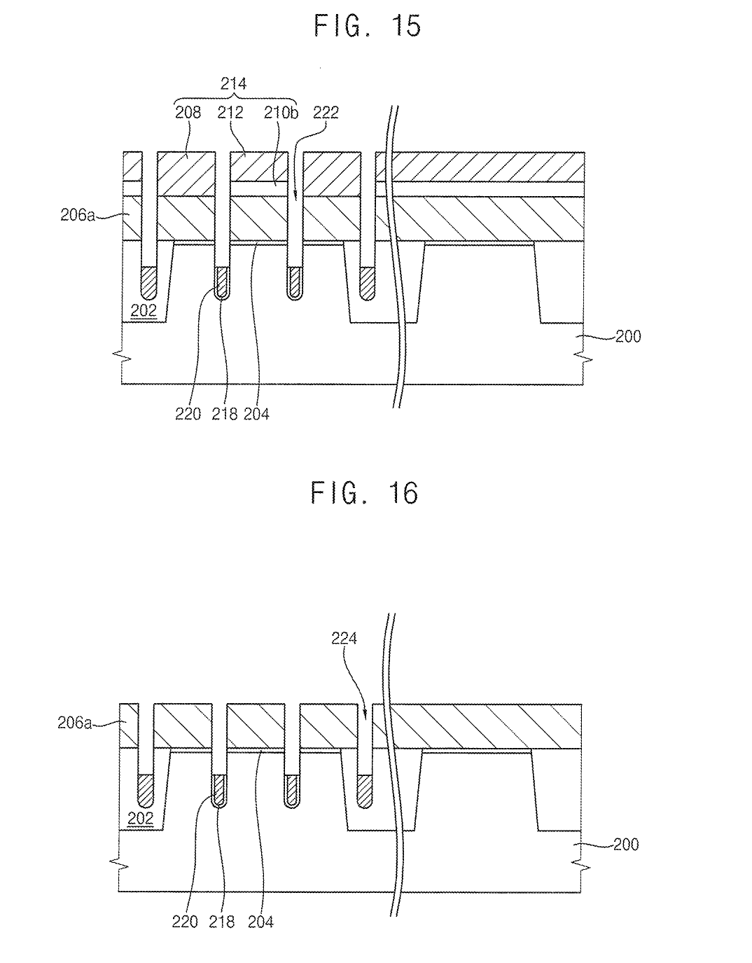

Referring to FIG. 15, a third silicon oxide layer is formed by oxidizing surface of the gate trench 216. The third silicon oxide layer is used as a first gate oxide layer 218.

Then, a layer of material such as titanium nitride (not shown) is formed to fill the gate trench and gaps between stacked layer structures wherein the first polysilicon layer pattern 206a and first silicon oxide layer 204 are stacked. The titanium nitride layer may be formed by a CVD process or an atomic layer deposition (ALD) process.

Thereafter, a first gate electrode pattern 220 is formed to partially fill the gate trench by etching back the titanium nitride layer though dry etching process. Here, an etching process is performed so that an upper surface of the first gate electrode pattern 220 is lower than that of the substrate 200.

By performing the etching process, a first opening 222 is formed in gaps of the first silicon oxide layer 204, the first polysilicon layer pattern 206a and the second hard mask pattern 214 formed in the first region of the substrate 200. Further, the titanium nitride layer formed in the second region may be completely removed by the etching process. Therefore, the second hard mask pattern 214 in the second region may be exposed.

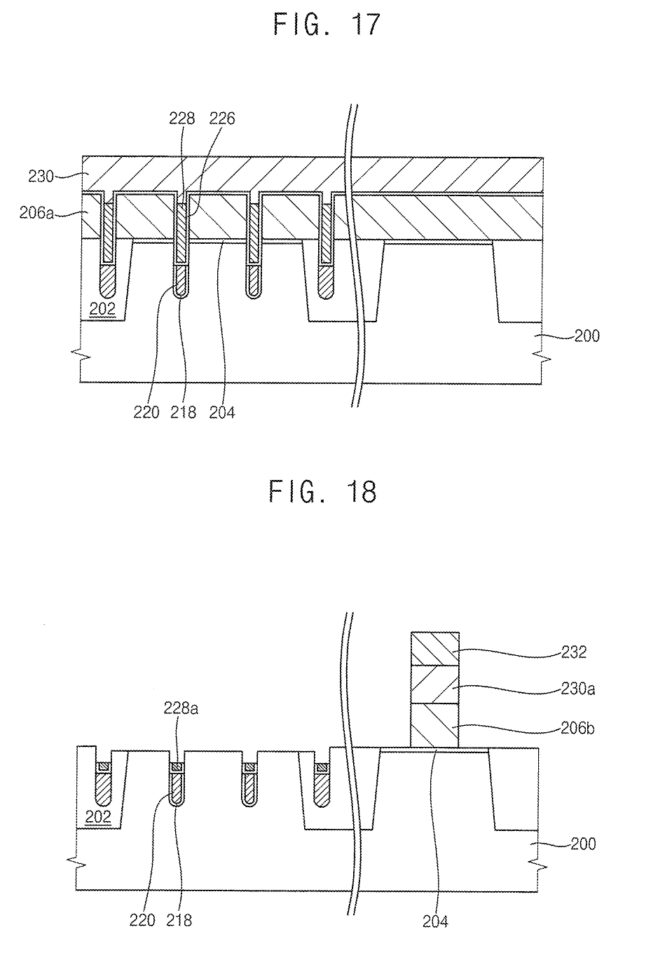

Referring to FIG. 16, the second hard mask pattern 214 formed in the first and second regions is removed. To remove the second hard mask pattern 214, silicon oxide may be etched after silicon nitride is etched.

Removal of the second hard mask pattern 214 may be performed by a wet etching process, a dry etching process or a combination thereof. A second opening 224 having a depth lower than that of the first opening 222 is formed at gaps of the first silicon oxide layer 204 and the first polysilicon layer pattern 206a by removing the second hard mask pattern 214.

Referring to FIG. 17, a passivation layer pattern 228 is formed by etching back after a passivation layer is formed to completely fill the second opening 224. The passivation layer pattern 228 may include a material such as silicon nitride, silicon oxynitride, polysilicon or the like or a combination thereof.

Before the passivation layer pattern 228 is formed, a fourth silicon oxide layer 226 is formed on the substrate 200 and inner surfaces of the second opening. The fourth silicon oxide layer 226 is formed to cure damage to the active region in a removing process of the second hard mask patterns 214 and an etching process to form the first gate electrode layer pattern 220.

Hereinafter, an example process of forming the passivation layer pattern 228 from polysilicon will now be explained.

First, a fourth silicon oxide layer 226 is deposited along an exposed surface of the polysilicon layer pattern 206a and the second opening 224. The fourth silicon oxide layer 226 may, for example, be formed by a CVD or a thermal oxidation process.

Then, a second polysilicon layer (not shown) is formed on the fourth silicon oxide layer 226 to completely fill the second opening 224. Then, a passivation layer pattern 228 is formed on the first gate electrode layer pattern 220 by etching-back the second polysilicon layer. Here, an upper surface of the passivation layer pattern 228 may be lower than that of the first polysilicon layer pattern 206a. That is, a portion wherein the passivation layer pattern 228 is formed may have a relatively lower step portion.

Thereafter, a tungsten silicide layer 230 is formed on the first polysilicon layer pattern 206a and passivation layer pattern 228.

The tungsten silicide layer 230 may be formed by, for example, a CVD process using tungsten source gas and silicon source gas. Here, tungsten silicide layer 230 is formed on the first polysilicon layer pattern 206a and passivation layer pattern 228 in the first region. Therefore, an upper surface of the first gate electrode layer pattern 220 may not directly contact the tungsten silicide layer 230.

Also, the tungsten silicide layer 230 is formed on the first polysilicon layer pattern 206a in the second region. The tungsten silicide layer 230 is used as a portion of a gate electrode of a planar transistor subsequently formed in the second region.

Referring to FIG. 18, a third hard mask pattern 232 is formed on the tungsten silicide layer 230. The third hard mask pattern 232 is used as a mask to pattern a gate electrode of the planar transistor in the second region.

Also, the tungsten silicide layer formed in the first region may be completely removed in a following etching process. Therefore, the third hard mask pattern 232 may have a shape configured to expose the entire first region.

The tungsten silicide layer 230 and the first polysilicon layer pattern 206a are etched using the third hard mask pattern 232 as an etching mask to form a metal silicide layer pattern 230a and a conductive layer pattern 206b, respectively. Since the passivation layer pattern 228 includes polysilicon, the passivation layer pattern 228 may become narrower by slightly etching the passivation layer pattern 228. Since the first polysilicon layer pattern 206a formed in the first region may be completely removed, a passivation layer pattern 228a may have an upper surface lower than that of the silicon substrate 200 after the etching process is performed. Though not shown, there is no problem even if the passivation layer pattern 228 is completely removed in the etching process.

By performing the above-mentioned process, a first gate electrode structure of an embedded transistor is formed in the first region, and a second gate electrode structure of a planar transistor is formed in the second region.

Referring to FIG. 19, a silicon nitride layer (not shown) is formed on the substrate 200 whereon the first and second gate electrode structures are formed. Then, the silicon nitride layer is anisotropically etched to expose a surface of the substrate 200. By performing the anisotropic etching process, the silicon nitride layer partly remains on the passivation layer pattern 228a of the first region so that an upper passivation layer pattern 236 is formed. Further, spacers 234 may be formed on sidewalls of the second gate electrode structure by performing the anisotropic etching process.

Then, an etch-stop layer 238 is formed along upper surfaces of the substrate 200, the upper passivation layer pattern 236, the spacer 234 and the second gate structure. The etch-stop layer 238 may be formed by, for example, depositing a material such as silicon nitride using a CVD process.

Thereafter, first source/drain regions 225a and 225b are formed in the substrate next to the first gate electrode structure by implanting impurities under the surface of the substrate, and second source/drain regions 227 are formed in the substrate under sidewalls of the second gate electrode structure.

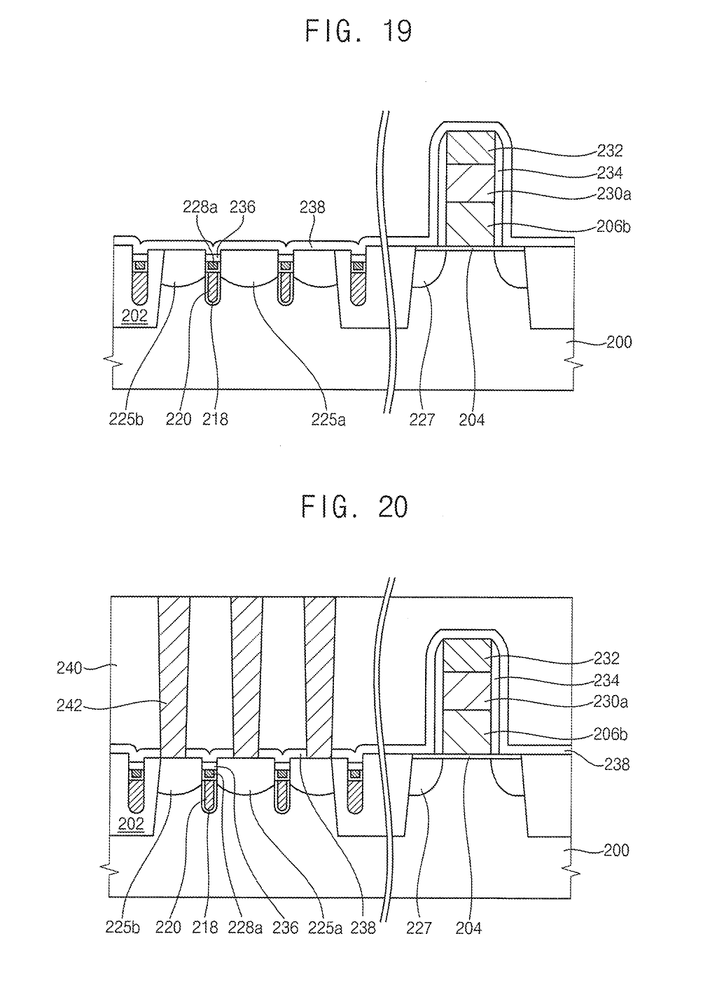

Referring to FIG. 20, a first insulating interlayer 240 is formed on the etch-stop layer 238.

A photoresist pattern (not shown) is formed by coating a photoresist film on the first insulating interlayer 240, and exposing and developing the photoresist film. The photoresist pattern is formed to selectively expose upper surfaces of the source/drain regions.

Then, contact holes exposing surfaces of the first and second source/drain regions are formed by etching the first insulating interlayer 240 and the etch-stop layer 238 using the photoresist pattern as an etching mask.

Since the first gate electrode 220 does not protrude above the surface of the substrate 200, spacers are not formed on sidewalls of the first gate electrode 220. As a result, distances between the first gate electrodes 220 become much wider than that of conventional gate electrodes. Therefore, misalignment margins may be increased when the contact hole is formed between the first gate electrodes.

A conductive layer is formed on the first insulating interlayer 240 to sufficiently fill up the contact hole. Then, a contact pad 242 is formed by polishing the conductive layer to expose a surface of the first insulating interlayer 240. Because distances between the first gate electrodes 220 are wider than that of conventional gate electrodes, a contact area of the contact pad 242 becomes much wider than that of conventional contact pads. As a result, the contact resistance of the contact pad 242 may be greatly reduced.

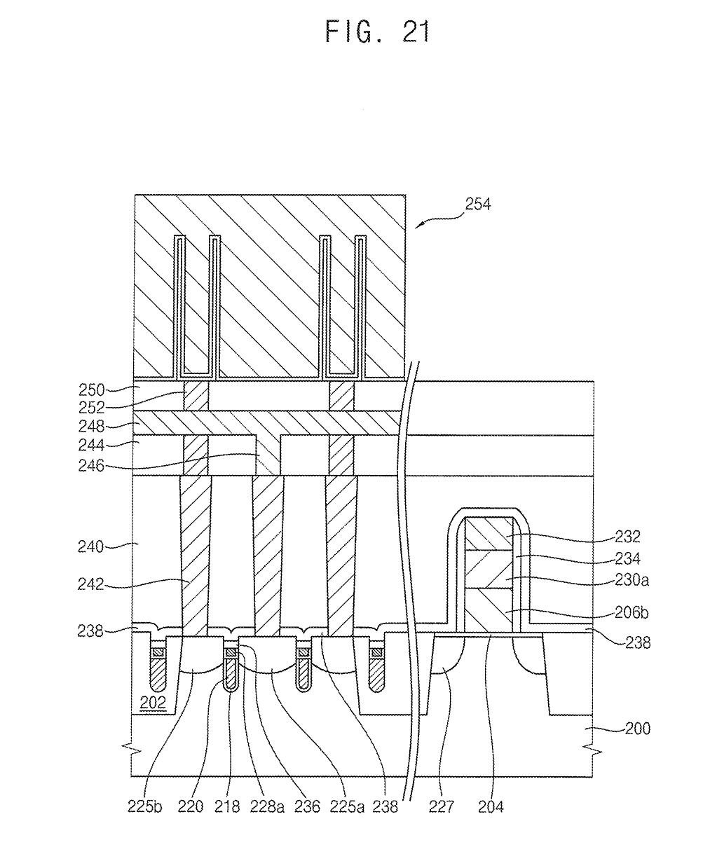

Referring to FIG. 21, a second insulating interlayer 244 is formed on the contact pad 242. A bit line contact 246 connected to a portion of the contact pad 242 is formed to penetrate inside the second insulating interlayer 244. Further, a bit line 248 connected to the bit line contact 246 may be formed on the second insulating interlayer 244.

Then, a third insulating interlayer 250 covering the bit line 248 is formed. A storage node contact 252 connected to the remaining contact pad 242 is formed to penetrate the third insulating interlayer 250 and the second insulating interlayer 244. Further, a cylindrical capacitor 254 electrically connected to the storage node contact 252 may be formed on the storage node contact 252.

Therefore, a DRAM device having an embedded transistor in a cell region may be completed.

Since the first gate electrode structure is embedded in the substrate, the bit line contact and storage node contact connecting directly to the surface of the substrate without forming an additional pad contact may be formed. Thus, manufacturing process costs may be reduced due to the omission of a step for forming the pad contact.

According to example embodiments described herein, a semiconductor device may be formed while reducing defects due to the difficulty of etching reactants generated by oxidation or changes at a portion where an embedded gate is formed. Therefore, the manufacturing yield of a semiconductor device may be improved and manufacturing process costs of the semiconductor device may be reduced.

The following paragraphs describe some exemplary embodiments of the present invention. These embodiments are illustrative and non-limiting.

According to one aspect of the present invention, a semiconductor device includes a substrate divided into a first region where a gate trench is formed and a second region, a first gate structure partially filling the gate trench, a passivation layer pattern provided in the gate trench and positioned on the first gate structure, first source/drains provided under surfaces of the substrate adjacent to sidewalls of the first gate structure, a second gate structure provided on a surface of the substrate of the second region, and having a shape in which a gate oxide layer, a conductive layer pattern and a metal silicide layer pattern are stacked, and second source/drain regions provided under surfaces of the substrate adjacent to sidewalls of the second gate structure.

According to one example embodiment, a gate electrode in the first gate structure may include metal. The gate electrode may include titanium nitride.

According to one example embodiment, the passivation layer pattern may include silicon nitride, silicon oxynitride, polysilicon, etc.

According to one example embodiment, a gate electrode in the second gate structure may have a stacked structure in which a silicon oxide layer, a polysilicon layer and a tungsten silicide pattern are stacked.

According to another aspect of the present invention, a method of manufacturing a semiconductor device according to one example embodiment of the present invention is provided. In the method of manufacturing the semiconductor device, a gate trench is formed by partially etching a first region of a substrate divided into the first region and a second region. A first gate structure partially fills the gate trench provided in the first region. A passivation layer pattern is formed on the first gate structure. A second gate structure having a shape in which a silicon oxide layer, a conductive layer pattern and a metal silicide layer pattern are stacked is formed on the substrate of the second region. First and second source/drain regions are formed respectively in the substrate adjacent to sidewalls of the first and second gate structures.

According to one example embodiment, in order to form the first gate structure, a gate oxide layer is formed on a side face and a bottom face of the gate trench. Then, a metal layer is formed to till up the gate trench. The metal layer is anisotropically etched to form a metal layer pattern partially filling the gate trench. Here, the metal layer pattern has an upper surface lower than an upper surface of the substrate.

Further, the metal layer may include titanium nitride.

The upper surface of the metal layer pattern may be formed to be positioned under the upper surface of the substrate by 200 to 1,000 Å.

According to one example embodiment, in order to form the gate trench, a silicon oxide layer and a conductive layer may be formed on the substrate of the first and second regions. Then, a mask pattern is formed on the first region by patterning only the conductive layer and the silicon oxide layer formed on the substrate of the first region and not patterning the conductive layer and the silicon oxide layer of the second region. Then, the substrate of the first region is etched using the mask pattern.

Further, the silicon oxide layer and the conductive layer may be used for forming a gate oxide layer and a gate electrode of the second gate structure.

To form the second gate structure, a metal silicide layer is formed on the mask pattern and the passivation layer pattern of the first region and the conductive layer of the second region. Then, a metal silicide layer pattern is formed on the second region while removing the metal silicide layer formed on the first region. Then, a conductive layer pattern is formed on the second region while removing the mask pattern formed on the first region. Furthermore, the metal silicide layer may include tungsten silicide.

According to one example embodiment, to form the passivation layer pattern, a passivation layer filling the gate trench is formed on the first gate structure. Then, the passivation layer is partially anisotropically etched.

Further, the passivation layer may include polysilicon, silicon nitride, silicon oxynitride, etc.

According to one example embodiment, after the first and second source/drain regions are formed, an insulation layer for a spacer may be formed on surfaces of the substrate and the passivation layer pattern of the first region, the substrate and the second gate structure of the second region. Also, the insulation layer may be anisotropically etched to form an upper passivation layer pattern on the passivation layer pattern, and spacers on sidewalls of the second gate structure.

Further, the upper passivation layer pattern may be formed to have an upper surface lower than an upper surface of the substrate.

According to one example embodiment, after the first and second source/drain regions, an insulating interlayer covering the second gate structure may be formed on the substrate of the first and second regions. Also, a contact hole exposing a surface of the substrate of the source/drain region may be formed by etching a portion of the insulating interlayer. Also, a contact pad may be formed by filling the contact hole with a conductive material.

According to another embodiment, a method of manufacturing a semiconductor device can be exemplarily characterized as including: providing a substrate having a first region and a second region; partially etching the first region of the substrate to form a gate trench; partially filling the gate trench provided in the first region of the substrate to form a first gate structure; forming a passivation layer pattern on the first gate structure; forming a second gate structure on a surface of the second region of the substrate, the second gate structure having a silicon oxide layer, a conductive layer pattern and a metal silicide layer pattern; and forming first and second source/drain regions adjacent to sidewalls of the first and second gate structures.

The first gate structure may be formed by: forming a gate oxide layer on a side face and a bottom face of the gate trench; filling the gate trench with a metal; and anisotropically etching the metal to form a metal layer pattern partially filling the gate trench and having an upper surface lower than an upper surface of the substrate.

The metal may include titanium nitride.

The upper surface of the metal layer pattern may be about 200 Å to about 1,000 Å lower than the upper surface of the substrate.

The gate trench may be formed by: forming a silicon oxide layer and a conductive layer on the first region and the second region of the substrate; forming a mask pattern in the first region of the substrate by patterning only the conductive layer and the silicon oxide layer in the first region of the substrate and not patterning the conductive layer or the silicon oxide layer in the second region of the substrate; and etching the first region of the substrate using the mask pattern.

The second gate structure may include a gate oxide layer and a gate electrode, wherein the gate oxide layer includes the silicon oxide layer and wherein the gate electrode includes the conductive layer.

The second gate structure may be formed by: forming a metal silicide layer on the mask pattern and passivation layer pattern in the first region of the substrate and on the conductive layer in the second region of the substrate; removing the metal silicide layer formed in the first region of the substrate to form a metal silicide layer pattern in the second region of the substrate; and removing the conductive layer formed in the first region of the substrate to form a conductive layer pattern in the second region of the substrate. The metal silicide layer may include tungsten silicide.

The passivation layer pattern may be formed by: forming a passivation layer on the first gate structure, the passivation layer filling the gate trench; and anisotropically etching the passivation layer, wherein the passivation layer pattern partially fills the gate trench.

The passivation layer may be formed by: depositing at least one selected from the group consisting of polysilicon, silicon nitride and silicon oxynitride.

The aforementioned method may further include: forming an insulation layer over the first region and second region of the substrate, on the passivation layer pattern in the first region of the substrate and on the second gate structure in the second region of the substrate; and anisotropically etching the insulation layer to form an upper passivation layer pattern on the passivation layer pattern and to form spacers on sidewalls of the second gate structure.

An upper surface of the upper passivation layer is lower than an upper surface of the substrate.

The aforementioned method may further include: forming an insulating interlayer in the first region and the second region of the substrate, the insulating interlayer covering the second gate structure; removing a portion of the insulating interlayer to form a contact hole exposing one of the source/drain regions; and forming a conductive material inside the contact hole to form a contact pad.

In a semiconductor de-vice formed by a method of the present invention, because the passivation layer pattern is formed on a first gate structure, reactants may hardly be formed by oxidation or changes in the first gate structure. Therefore, a semiconductor device may be formed while reducing defects generated by oxidation or changes in the first gate structure. Therefore, the manufacturing yield of a semiconductor device may be improved and manufacturing process costs of the semiconductor device may be reduced.

Also, a semiconductor device according to the present invention may have improved operating characteristics and high reliability.

The foregoing embodiments are illustrative of the present invention and are not to be construed as limiting thereof. Although a few example embodiments have been described, those skilled in the art will readily appreciate that many modifications are possible in the example embodiments without materially departing from the novel teachings and advantages of this invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A semiconductor device comprising:
a substrate having a first region and a second region, wherein a gate trench is formed in the first region;
a first gate structure partially filling the gate trench;
a passivation layer pattern provided in the gate trench and on the first gate structure;
first source/drain regions adjacent to sidewalls of the first gate structure;
a second gate structure provided on a surface of the substrate in the second region of the substrate, the second gate structure having a gate dielectric layer, a conductive layer pattern and a metal silicide layer pattern stacked on the conductive layer pattern; and
second source/drain regions adjacent to sidewalls of the second gate structure.

2. The semiconductor device of claim 1, wherein the first gate structure includes a gate electrode comprising a metal.

3. The semiconductor device of claim 2, wherein the metal comprises titanium nitride.

4. The semiconductor device of claim 1, wherein the passivation layer comprises at least one selected from the group consisting of silicon nitride, silicon oxynitride and polysilicon.

5. The semiconductor device of claim 1, wherein the conductive layer pattern comprises polysilicon and the metal silicide layer pattern comprises tungsten silicide.

6. The semiconductor device of claim 1, wherein the first gate structure comprises a gate dielectric layer provided on a side face and a bottom face of the gate trench.

7. The semiconductor device of claim 1, wherein an upper surface of first gate structure is about 200 Å to about 1,000 Å lower than an upper surface of the substrate.

8. The semiconductor device of claim 1, wherein an upper surface of the passivation layer pattern is below an upper surface of the substrate.

9. The semiconductor device of claim 1, further comprising:
an upper passivation layer pattern on the passivation layer pattern; and
spacers on sidewalls of the second gate structure,
wherein the upper passivation layer pattern and the spacers comprise the same material.

10. The semiconductor device of claim 9, wherein an upper surface of the upper passivation layer is lower than an upper surface of the substrate.

11. The semiconductor device of claim 1, further comprising:
an insulating interlayer in the first region and the second region of the substrate, the insulating interlayer covering the second gate structure, wherein a contact hole extends through the insulating interlayer to expose one of the first source/drain regions; and
a contact pad arranged within the contact hole, the contact pad comprising conductive material electrically connected to the one of the first source/drain regions.
